(19) United States
(12) Patent Application Publication
(10) Pub. No.: US 2026/0368905 A1
(43) Pub. Date: Nov. 19, 2026

(54) METHOD FOR DETECTING AN ARC STRIKING PHENOMENON IN POWER DISTRIBUTION CABINET

(71) Applicants: ELECTRIC POWER RESEARCH INSTITUTE OF STATE GRID SHANXI ELECTRIC POWER CO., LTD, Shanxi (CN); BEIJING JUDA INFORMATION TECHNOLOGY CO., LTD, Beijing (CN)

(72) Inventors: Wei WANG, Shanxi (CN); Yudong XU, Shanxi (CN); Hong LIU, Shanxi (CN); Yichen YU, Shanxi (CN); Zhixiang LIU, Shanxi (CN); Yutong CHEN, Shanxi (CN); Shixuan LV, Shanxi (CN); Yushen LI, Beijing (CN); Huibin YUAN, Shanxi (CN); Xiaojing LI, Shanxi (CN)

(21) Appl. No.: 19/573,136

(22) Filed: Mar. 20, 2026

Related U.S. Application Data
(63) Continuation of application No. PCT/CN2026/072899, filed on Jan. 15, 2026.

(30) Foreign Application Priority Data
May 14, 2025 (CN) 202510618039.8

(51) Int. Cl. G06T 7/187; G01R 31/52

(52) U.S. Cl. CPC G06T 7/187; G01R 31/52; G06T 2207/10021

(57) ABSTRACT

Provided are a method for detecting an arc striking phenomenon in a power distribution cabinet. The method includes the following: a cabinet interior image of the power distribution cabinet is acquired; and when an elongated highlight region exists in the cabinet interior image, end regions corresponding to two ends of the elongated highlight region are constructed; it is judged whether the number of elongated highlight targets contained in each sub-region is 1; if so, it is judged whether a brightness difference between the two end regions of the elongated highlight region is greater than a preset brightness difference threshold; if so, it is judged whether a brightness change from one end to the other end is monotonically increasing or monotonically decreasing; and if so, it is determined that the arc striking phenomenon occurs in the power distribution cabinet.

### CROSS-REFERENCE TO RELATED APPLICATIONS

This is a continuation of International Patent Application No. PCT/CN2026/072899, filed on Jan. 15, 2026, which claims priority to Chinese Patent Application No. 202510618039.8 filed with the China National Intellectual Property Administration (CNIPA) on May 14, 2025, the disclosures of which are incorporated herein by reference in their entireties.

### TECHNICAL FIELD

The present application relates to the technical field of safety detection of power distribution cabinets, for example, a method for detecting an arc striking phenomenon in a power distribution cabinet.

### BACKGROUND

In a modern power system, a power distribution cabinet is one of the key facilities in the process of power transmission and distribution. Many key components are usually arranged in the power distribution cabinet, such as a busbar and a terminal head. These components play an important role in the power transmission and distribution and work together to guarantee that power can be safely, stably and efficiently delivered to various electrical devices and regions.

During the actual operation of a power distribution station, due to climate reasons, accidents caused by condensation occur from time to time. This is mainly because the power distribution cabinet device is usually connected to a cable channel due to the needs of cable incoming and outgoing. In rainy seasons such as summer, humidity in the cable channel is usually high due to rainfall water accumulation and poor ventilation. A large amount of moisture accumulates in the cable channel, laying a hidden danger for subsequent problems. In cold seasons such as autumn and winter, the situation is also not optimistic. The temperature in the cable channel is higher than the outdoor ambient temperature. When the sealing of a cable hole is not ideal, high-temperature and high-humidity air enters the power distribution cabinet from the bottom. In the low temperature environment in the cabinet, the air may be supersaturated with water vapor, and part of the water vapor may condense and precipitate to cover the surface of the device. Such condensed water vapor may reduce the insulation performance of devices such as a cable terminal and an insulating sleeve. When the insulation performance drops to a certain extent, it may easily cause an arc striking phenomenon. For example, at an electrical connection point of the devices, the current passes through stably when the insulation performance is good. However, when the insulation performance deteriorates due to condensation, air is broken down to form an arc. This kind of arc striking is easy to form abnormal phenomena such as flashover, which can not only directly lead to a device operation failure but also induce the internal defects of the device to develop into the operation failure in advance. In severe cases, the arc striking may cause insulation breakdown. A strong current may cause the terminal to be burnt and even trigger a cabinet explosion, posing a serious threat to the safe and stable operation of the power distribution station.

Due to the discontinuous occurrence of the arc striking phenomenon, it poses a great challenge to conventional inspection methods. The conventional inspection methods mostly rely on manual periodic inspection, with the inspection cycle usually measured in days, weeks, or even months. In such a long time interval, the arc striking phenomenon may only occur for a short moment. If the time of arc striking is not within the inspection period of the inspectors, the arc striking phenomenon will be easily missed. Moreover, the environment in the power distribution cabinet is relatively complex. Many electrical elements and circuits exist in the power distribution cabinet. These devices may also generate various signals like sound and heat during normal operation, which can easily interfere with the judgment by inspectors on the arc striking phenomenon, making it difficult for the inspectors to accurately identify the arc striking phenomenon from complicated background information even when they are on site.

### SUMMARY

To solve the preceding technical problem, the present application provides a method for detecting an arc striking phenomenon in a power distribution cabinet. The method includes the steps below.

A cabinet interior image of the power distribution cabinet is acquired; and when an elongated highlight region exists in the cabinet interior image, end regions corresponding to two ends of the elongated highlight region are constructed.

The elongated highlight region is divided into multiple sub-regions; it is judged whether the number of elongated highlight targets contained in each sub-region is 1; if the number of elongated highlight targets contained in each sub-region is 1, it is judged whether a brightness difference between the two end regions of the elongated highlight region is greater than a preset brightness difference threshold; if the brightness difference between the two end regions of the elongated highlight region is greater than the preset brightness difference threshold, it is judged whether a brightness change from one end to the other end is monotonically increasing or monotonically decreasing; and if the brightness change from the one end to the other end is monotonically increasing or monotonically decreasing, it is determined that the arc striking phenomenon occurs in the power distribution cabinet.

In some embodiments, the cabinet interior image is input into a pre-trained target detection model to identify a highlight-located box region in the cabinet interior image.

It is judged whether an aspect ratio of the highlight-located box region in the cabinet interior image is greater than a preset ratio, if the aspect ratio of the highlight-located box region in the cabinet interior image is greater than the preset ratio, it is determined that a highlight region in the highlight-located box region is elongated, and the highlight region is extracted to obtain the elongated highlight region.

In some embodiments, after it is determined that the arc striking phenomenon occurs in the power distribution cabinet, it is judged whether a highlight-located box region with an aspect ratio in a preset range exists in a cabinet interior image after an interval of one time sequence; if the highlight-located box region with the aspect ratio in the preset range exists in the cabinet interior image after the interval of one time sequence, it is judged whether the elongated highlight region used as a basis for determining the arc striking phenomenon exists in a previous time sequence; if the elongated highlight region used as the basis for determining the arc striking phenomenon exists in the previous time sequence, it is judged whether the highlight-located box region overlaps the elongated highlight region used as the basis for determining the arc striking phenomenon in the previous time sequence; and if the highlight-located box region overlaps the elongated highlight region used as the basis for determining the arc striking phenomenon in the previous time sequence, it is determined that a gas flow-contacting arc phenomenon occurs in the power distribution cabinet in the current time sequence; where an upper limit of the preset range is less than the preset ratio.

After it is determined that the gas flow-contacting arc phenomenon occurs in the power distribution cabinet, it is judged whether a highlight-located box region with an aspect ratio in the preset range exists in a cabinet interior image after an interval of one time sequence; if the highlight-located box region with the aspect ratio in the preset range exists in the cabinet interior image after the interval of one time sequence, it is judged whether no arc striking phenomenon occurs in the power distribution cabinet in the current time sequence; and if no arc striking phenomenon occurs in the power distribution cabinet in the current time sequence, it is determined that a high-intensity gas flow arc-blowing phenomenon occurs in the power distribution cabinet in the current time sequence.

When the arc striking phenomenon, the gas flow-contacting arc phenomenon, and the high-intensity gas flow arc-blowing phenomenon occur sequentially in the power distribution cabinet in three consecutive and adjacent time sequences, it is determined that a flashover phenomenon occurs in the power distribution cabinet.

In some embodiments, an end region corresponding to each end of the two ends is constructed based on two end positions of the elongated highlight region and an average width of the elongated highlight region.

In some embodiments, an acquisition process of the average width of the elongated highlight region includes the following.

Multiple line segments penetrating the elongated highlight region are drawn with a preset interval according to a direction perpendicular to a long side of the minimum bounding rectangle of the elongated highlight region; and an average value of a distance between two points where each line segment intersects a boundary of the elongated highlight region is calculated and taken as the average width of the elongated highlight region.

In some embodiments, constructing the end region corresponding to each end based on the two end positions of the elongated highlight region and the average width of the elongated highlight region includes the following.

Each end position is taken as the center and the average width of the elongated highlight region is taken as a side length or a diameter to construct a square region or a circular region as the end region corresponding to each end.

In some embodiments, if an angle between a line connecting the one end to the other end of the elongated highlight region and the horizontal direction is less than 45°, the elongated highlight region is vertically divided into the plurality of sub-regions.

If the angle between the line connecting the one end to the other end of the elongated highlight region and the horizontal direction is greater than 45°, the elongated highlight region is horizontally divided into the plurality of sub-regions.

If the angle between the line connecting the one end to the other end of the elongated highlight region and the horizontal direction is equal to 45°, the elongated highlight region is horizontally or vertically divided into the plurality of sub-regions.

In some embodiments, if the number of elongated highlight targets contained in a sub-region in the elongated highlight region is greater than 1, it is determined that the elongated highlight region does not meet a condition for the arc striking phenomenon, no subsequent judgment is performed, and a next elongated highlight region is processed.

In some embodiments, an average value of brightness of all pixels in each sub-region is taken as brightness of each sub-region.

Among the plurality of sub-regions, a brightness difference between brightness of a next sub-region and brightness of a previous sub-region is determined according to an extension direction from one end to the other end of the elongated highlight region to obtain (N−1) brightness differences, where N denotes the number of the sub-regions.

Among the (N−1) brightness differences, the number of brightness differences greater than 0 and the number of brightness differences less than 0 are counted; if the number of brightness differences greater than 0 is greater than a preset brightness difference count judgment threshold, it is determined that the brightness from the one end to the other end of the elongated highlight region is monotonically increasing; and if the number of brightness differences less than 0 is greater than the preset brightness difference count judgment threshold, it is determined that the brightness from the one end to the other end of the elongated highlight region is monotonically decreasing.

The present application further provides a system for detecting an arc striking phenomenon in a power distribution cabinet. The system includes an image collection module, an end region construction module, and a judgment module.

The image collection module is configured to acquire a cabinet interior image of the power distribution cabinet.

The end region construction module is configured to, when an elongated highlight region exists in the cabinet interior image, construct end regions corresponding to two ends of the elongated highlight region.

The judgment module is configured to: divide the elongated highlight region into a plurality of sub-regions; judge whether a number of elongated highlight targets contained in each sub-region among the plurality of sub-regions is 1; if the number of elongated highlight targets contained in each sub-region is 1, judge whether a brightness difference between the two end regions of the elongated highlight region is greater than a preset brightness difference threshold; if the brightness difference between the two end regions of the elongated highlight region is greater than the preset brightness difference threshold, judge whether a brightness change from one end to the other end is monotonically increasing or monotonically decreasing; and if the brightness change from the one end to the other end is monotonically increasing or monotonically decreasing, determine that the arc striking phenomenon occurs in the power distribution cabinet.

The technical solutions of the present application have the beneficial effects below compared with the related art.

According to the method and system for detecting an arc striking phenomenon in a power distribution cabinet according to the present application, image detection is performed on the cabinet interior image of the power distribution cabinet, thereby breaking through the time limit of conventional inspection and implementing continuous monitoring on internal conditions of the power distribution cabinet. Because the power distribution cabinet is usually dark, when an arc striking phenomenon occurs in the power distribution cabinet, it may emit a highlight and usually presents an elongated shape according to factors such as the action of current and the flow of gas. The present application makes use of this feature. In the present application, when an elongated highlight region exists in the cabinet interior image, it is preliminarily judged that the arc striking phenomenon may occur. Considering that the highlight in the power distribution cabinet may be caused by other factors such as light leakage from a power distribution box and the reflection from a device, this application further combines other features of arc striking to make an accurate judgment. A feature of the arc striking phenomenon is that the arc is curved but not spiral. On this basis, the elongated highlight region is divided into multiple sub-regions. It is judged whether the number of elongated highlight targets contained in each sub-region is 1, thereby eliminating partial interference. Moreover, a feature of the arc striking phenomenon is that the brightness decreases gradually from the head to the tail. On this basis, if the brightness difference between the two end regions is greater than the preset brightness difference threshold and the brightness from one end to the other end is monotonically increasing or monotonically decreasing, the highlight interference caused by other factors can be effectively eliminated through integration with various features of the arc striking phenomenon, implementing the accurate identification of the arc striking phenomenon in the power distribution cabinet, breaking through the time limit of conventional inspection, enabling the continuous monitoring on the internal condition of the power distribution cabinet, and greatly improving the accuracy of judging the arc striking phenomenon in a complex environment. Additionally, the arc striking phenomenon in the power distribution cabinet is accurately identified to perform intervening and effectively prevent the device failure before an electrical device fails, reducing the complexity of failure, preventing a large number of components from being damaged and an increase in maintenance difficulty due to the deterioration of failure, and thus reducing the maintenance cost.

Additionally, in the case of a gas flow-contacting arc phenomenon, when the gas flow comes into contact with the burning arc, the gas flow may cause disturbance to the arc and change the gas flow field and energy distribution around the arc. On the cabinet interior image, this disturbance is represented as a region with a large area overlapping the original elongated highlight region. Therefore, after it is determined that the arc striking phenomenon occurs in the power distribution cabinet in the present application, it is judged whether a region with a large area exists in the cabinet interior image after the interval of one time sequence. The region with the large area refers to a region where the aspect ratio of an elongated highlight region is within a set ratio range. Moreover, it is judged whether the elongated highlight region used as the basis for determining the arc striking phenomenon exists in the previous time sequence. If the region with a large area exists in the cabinet interior image after the interval of one time sequence and the elongated highlight region used as the basis for determining the arc striking phenomenon exists in the previous time sequence, it is judged whether the highlight-located box region overlaps the elongated highlight region used as the basis for determining the arc striking phenomenon in the previous time sequence. If the highlight-located box region overlaps the elongated highlight region used as the basis for determining the arc striking phenomenon in the previous time sequence, it is determined that the gas flow-contacting arc phenomenon occurs in the power distribution cabinet in the current time sequence. When the gas flow-contacting arc phenomenon occurs, the strong gas flow may blow away the arc, causing the arc to be extinguished. In this case, no new arc striking phenomenon occurs in the distribution cabinet. However, the energy of the gas flow still exists and may form a region with a large area on the cabinet interior image. Therefore, after it is determined that the gas flow-contacting arc phenomenon occurs in the power distribution cabinet in the present application, it is judged whether a highlight-located box region with the aspect ratio in the preset range exists in the cabinet interior image after the interval of one time sequence and whether no arc striking phenomenon occurs in the power distribution cabinet. If the highlight-located box region with the aspect ratio in the preset range exists in the cabinet interior image after the interval of one time sequence and no arc striking phenomenon occurs in the power distribution cabinet, it is determined that the high-intensity gas flow arc-blowing phenomenon occurs in the power distribution cabinet in the current time sequence. The arc striking is the initial stage of the flashover. Then the gas flow contacts the arc, changing the shape and energy distribution of the arc. Finally, the gas flow strongly blows the arc, causing the arc to be extinguished or the energy of the arc to be greatly weakened. Therefore, in the present application, it is judged whether the arc striking phenomenon, the gas flow-contacting arc phenomenon, and the high-intensity gas flow arc-blowing phenomenon occur sequentially in the power distribution cabinet in three consecutive and adjacent time sequences, it is judged whether the flashover phenomenon occurs in the power distribution cabinet, preventing the flashover phenomenon from threatening the safe and stable operation of a power distribution station and guaranteeing the safe and stable operation of the power distribution cabinet.

### BRIEF DESCRIPTION OF DRAWINGS

In order to make the content of the present application more clearly understood, the present application is described in further detail hereinafter according to specific embodiments of the present application in combination with the drawings.

FIG. 1 is a flowchart of a method for detecting an arc striking phenomenon in a power distribution cabinet according to the present application.

FIG. 2 is a diagram illustrating the extraction of an elongated highlight region.

FIG. 3A is a diagram illustrating that the elongated highlight region is divided into a plurality of sub-regions in the horizontal direction and the number of elongated highlight targets in each sub-region is 1.

FIG. 3B is a diagram illustrating that the elongated highlight region is divided into a plurality of sub-regions in the horizontal direction and two or more elongated highlight targets exist in a sub-region.

FIG. 4 is a flowchart illustrating the identification of a flashover phenomenon.

FIG. 5 is a diagram of an identified highlight-located box region in the case where a cabinet interior image includes a current image.

FIG. 6 is a structural diagram of a device for detecting an arc striking phenomenon in a power distribution cabinet according to an embodiment of the present application.

### DETAILED DESCRIPTION

The present application is further described hereinafter in combination with the drawings and specific embodiments to enable those skilled in the art to better understand and implement the present application, but these embodiments are not intended to limit the present application.

In a power system, an arc striking phenomenon is often hidden in a power distribution cabinet. Because of its discontinuous occurrence, such a phenomenon is not easily detected in a conventional inspection manner. Therefore, embodiment one provides a method for detecting an arc striking phenomenon in a power distribution cabinet, which can accurately and timely detect whether an abnormal phenomenon of arc striking occurs in the power distribution cabinet.

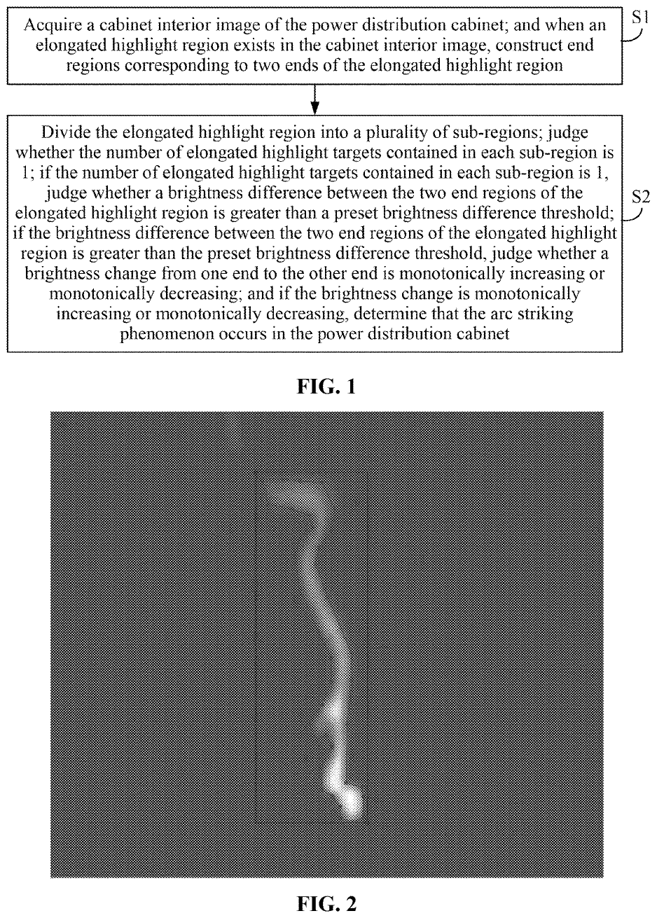

Referring to FIG. 1, embodiment one of this application provides a method for detecting an arc striking phenomenon in a power distribution cabinet. The method includes the steps below.

In step S1, a cabinet interior image of the power distribution cabinet is acquired; and when an elongated highlight region exists in the cabinet interior image, end regions corresponding to two ends of the elongated highlight region are constructed.

In this embodiment, specifically, the acquisition process of the elongated highlight region in the cabinet interior image is as follows.

A highlight-located box region in the cabinet interior image is detected based on the cabinet interior image, and the elongated highlight region is extracted through an image segmentation model from the highlight-located box region in the cabinet interior image. The image segmentation model includes any one of a U-Net model, a SegNet model, or a fully convolutional network (FCN) model.

The highlight is framed through the box. The formula for the identified highlight-located box region in the cabinet interior image is as follows:
box=(bx, by, bw, bh)

Here box denotes the highlight-located box region in the cabinet interior image. bx denotes the x-axis coordinate of a vertex of the highlight-located box region. by denotes the y-axis coordinate of the vertex of the highlight-located box region. bw denotes the width of the highlight-located box region. bh denotes the height of the highlight-located box region.

The method of detecting the highlight-located box region in the cabinet interior image is any one of a pre-trained target detection model or a region detection algorithm.

The target detection model is any one of a YOLOv10_L target detection model, a Faster R-CNN model, or a Mask R-CNN model. The region detection algorithm is any one of OpenCV region detection algorithms or Canny edge detection algorithms.

In this embodiment, specifically, when the aspect ratio of the highlight-located box region in the cabinet interior image is greater than a preset ratio, it is determined that a highlight region in the highlight-located box region is elongated. Here, the preset ratio is in the range of 3 to 8; alternatively, other larger ratios may be selected, which is not specifically limited in the present application.

The elongated shape is a straight elongated shape or a curved elongated shape, which is not specifically limited in the present application. As arc striking is usually in a curved elongated shape, the preceding elongated highlight region is usually a curved elongated region.

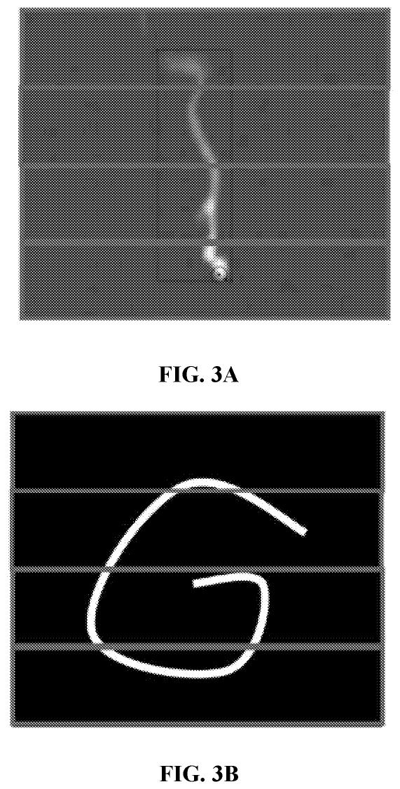

As shown in FIG. 2, FIG. 2 is a diagram illustrating the extraction of an elongated highlight region. The elongated highlight region in FIG. 2 is a curved elongated region.

In this embodiment, the highlight-located box region in the cabinet interior image is detected, and then the elongated highlight region is extracted from the highlight-located box region. Such an arrangement can accurately extract the elongated highlight region in the image and effectively eliminate the interference of other irrelevant information in the image with a mere focus on a key part related to abnormality. Compared with a traditional manner of directly analyzing the whole image, this method greatly improves the accuracy of abnormality detection. Many factors that may affect judgment exist in a complex cabinet environment, such as the reflection of a device itself and the lighting of a normal indicator. The method in this embodiment can accurately identify the highlight part that really represents abnormality, reduce misjudgment, and thus provide a more reliable data basis for the analysis and processing of the arc striking phenomenon, guaranteeing the accuracy and reliability of the identification result of the arc striking phenomenon.

In this embodiment, specifically, that the end regions corresponding to the two ends of the elongated highlight region are constructed includes the following.

With each end taken as a center, a region composed of pixels within a range less than or equal to a preset distance is taken as an end region corresponding to the end.

Two end positions of the elongated highlight region are P₁ and P₂. The coordinates of P₁ are (pₓ₁, p_{y1}). The coordinates of P₂ are (pₓ₂, p_{y2}). The two end positions of the elongated highlight region are positions where the two ends of the elongated highlight region are located.

In this embodiment, an end region corresponding to each end is constructed based on the two end positions of the elongated highlight region and the average width of the elongated highlight region.

In one or more embodiments, each end position is taken as the center and the average width of the elongated highlight region is taken as a side length to construct a square region as the end region corresponding to the end, which is presented in the following formulas:

box_{head}=Rect(pₓ₁−w/2, p_{y1}−w/2, pₓ₁+w/2, p_{y1}+w/2)

boxₜₐᵢₗ=Rect(pₓ₂−w/2,p_{y2}−w/2,pₓ₂+w/2,p_{y2}+w/2)

box_{head} denotes an end region corresponding to a head end. boxₜₐᵢₗ denotes an end region corresponding to a tail end. The coordinates of the head end position P₁ are (pₓ₁, p_{y1}). The coordinates of the tail end position P₂ are (pₓ₂, p_{y2}). pₓ₁ denotes the abscissa of the head end position P₁. p_{y1} denotes the ordinate of the head end position P₁. pₓ₂ denotes the abscissa of the tail end position P₂. p_{y2} denotes the ordinate of the tail end position P₂. w denotes the average width of the elongated highlight region. Rect(·) is a function representation for constructing a rectangular region.

In one or more embodiments, each end position is taken as the center and the average width of the elongated highlight region is taken as a side length to construct a circular region as the end region corresponding to the end.

In this embodiment, the end region corresponding to each end is constructed based on the two end positions of the elongated highlight region and the average width of the elongated highlight region so that the entire width of the determined end region is consistent with the entire width of the elongated highlight region, thus fully reflecting the entire brightness of each end region and not affecting the accuracy of the brightness of the end region due to an excessively large range of the end region.

In the present application, specifically, the acquisition process of the average width of the elongated highlight region includes the following.

A plurality of line segments penetrating the elongated highlight region are drawn at preset intervals according to a direction perpendicular to a long side of the minimum bounding rectangle of the elongated highlight region, and the average value of the distance between two points where each line segment intersects a boundary of the elongated highlight region is calculated and taken as the average width of the elongated highlight region.

In one or more embodiments, the plurality of line segments penetrating the elongated highlight region are drawn at preset intervals according to the direction perpendicular to a semi-major axis of the minimum bounding ellipse of the elongated highlighted region, and the average value of the distance between two points where each line segment intersects a boundary of the elongated highlight region is calculated and taken as the average width of the elongated highlight region.

In one or more embodiments, the elongated highlight region is divided into S highlight sections along the extension direction from one end to the other end of the elongated highlight region, and the average value of the widths of the S highlight sections is taken as the average width of the elongated highlight region, which is presented in the following formula:

w=mean (w₁+w₂+ . . . +w_{S})

w denotes the average width of the elongated highlight region. mean(·) is an average value function. wₙ denotes the width of an n-th highlight section. n=1, 2, . . . , S.

The width of each highlight section may be determined in multiple ways, which is specifically described as below.

For each highlight section, a position inside the highlight section is arbitrarily selected. From the selected position and in the extension direction from one end to the other end of the elongated highlight region, the distance from the selected position to the boundary at one side of the current highlight section is measured and taken as the width of the current highlight section.

For each highlight section, a central position inside the highlight section is determined. From the central position and in the extension direction from one end to the other end of the elongated highlight region, the distance from the central position to the boundary at one side of the current highlight section is measured and taken as the width of the current highlight section.

For each highlight section, multiple positions inside the highlight section are arbitrarily selected. From each selected position and in the extension direction from one end to the other end of the elongated highlight region, the average value of the distance from each selected position to the boundary at one side of the current highlight section is calculated and taken as the width of the current highlight section.

In step 2, the elongated highlight region is divided into a plurality of sub-regions; it is judged whether the number of elongated highlight targets contained in each sub-region is 1; if the number of elongated highlight targets contained in each sub-region is 1, it is judged whether a brightness difference between the two end regions of the elongated highlight region is greater than a preset brightness difference threshold; if the brightness difference between the two end regions of the elongated highlight region is greater than the preset brightness difference threshold, it is judged whether a brightness change from one end to the other end is monotonically increasing or monotonically decreasing; and if the brightness change from one end to the other end is monotonically increasing or monotonically decreasing, it is determined that the arc striking phenomenon occurs in the power distribution cabinet.

In this embodiment, specifically, the division direction is determined according to the extension direction from one end to the other end, and the elongated highlight region is divided into the plurality of sub-regions.

The extension direction from one end to the other end is, according to the curved profile of the elongated highlight region, starting from a starting end and conforming to the trend of the curve until reaching the other end. For ease of calculation, the extension direction of one end to the other end may also be the linear connection direction of one end to the other end.

If the angle between the line connecting one end to the other end of the elongated highlight region and the horizontal direction is less than 45°, the elongated highlight region is vertically divided into the plurality of sub-regions.

If the angle between the line connecting one end to the other end of the elongated highlight region and the horizontal direction is greater than 45°, the elongated highlight region is horizontally divided into the plurality of sub-regions.

If the angle between the line connecting one end to the other end of the elongated highlight region and the horizontal direction is equal to 45°, the elongated highlight region is horizontally or vertically divided into the plurality of sub-regions.

Here the angle between the linear connection direction from one end to the other end of the elongated highlight region and the horizontal direction may be expressed by a tilt angle θ. The formula for the tangent of the tilt angle θ is as follows.

$$tan θ = \frac{( {p}_{y 2} - {p}_{y 1} )}{( {p}_{x 2} - {p}_{x 1} )}$$

θ denotes the tilt angle. tanθ denotes the tangent of the tilt angle θ.

If the angle between the linear connection direction from one end to the other end of the elongated highlight region and the horizontal direction is less than 45°, that is, if −1<tanθ<1, it indicates that the entire elongated highlight region extends horizontally; therefore, the division direction is set to be vertical so that the elongated highlight region can be divided into the plurality of sub-regions in the length direction of the elongated highlight region. Similarly, if the angle between the linear connection direction from one end to the other end of the elongated highlight region and the horizontal direction is greater than 45°, that is, if tanθ>1 or tanθ<−1, it indicates that the entire elongated highlight region extends vertically; therefore, the division direction is set to be horizontal.

Different division manners are adopted for elongated highlight regions of different angles. The elongated highlight region may be divided into N parts in the length direction of the elongated highlight region so that the divided sub-areas can better fit the actual shape of the arc. In this case, in the analysis of brightness distribution, the monotonic change of brightness from one end to the other and the brightness of each end region can be more accurately captured with no detection loophole caused by the diversity of arc shapes, guaranteeing that the arc striking phenomenon in the power distribution cabinet can be accurately determined in various complex situations.

As shown in FIG. 3, FIG. 3 is a diagram illustrating that the elongated highlight region is divided into the plurality of sub-regions in the horizontal direction.

In the present application, the elongated highlight region may be evenly divided into the plurality of sub-regions; alternatively, the cabinet interior image may be divided into a plurality of sub-regions in the extension direction from one end to the other end, and the elongated highlight region is contained in each sub-region so that the elongated highlight region is divided into multiple parts; alternatively, the elongated highlight region may be divided into the plurality of sub-regions with different areas. This is not limited in the present application.

FIG. 3A illustrates a diagram where the number of elongated highlight targets in each sub-region is 1. FIG. 3B illustrates a diagram where two or more elongated highlight targets exist in a sub-region. When the elongated highlight region is spiral, two or more elongated highlight targets may exist in a sub-region. In this case, it indicates that the highlight in the elongated highlight region is not caused by the arc striking phenomenon but may be caused by other reasons, such as light leakage from a power distribution box. Since the feature of the arc striking phenomenon is that the arc is curved but not spiral, when the number of elongated highlight targets contained in each sub-region is 1, it indicates that the feature of the arc striking phenomenon is met; in this manner, partial interference can be eliminated, thereby more accurately judging whether the arc striking phenomenon occurs in the power distribution cabinet.

In the arc striking phenomenon, the brightness of the arc striking head is usually high, and the brightness of the arc striking tail is usually low. Therefore, when it is judged whether a suspected arc striking region is actually an arc striking region, it needs to detect whether a brightness difference between two end regions of the suspected arc striking region is greater than the preset brightness difference threshold. If the brightness difference between the two end regions of the suspected arc striking region is greater than the preset brightness difference threshold, it indicates that the suspected arc striking region meets the condition that the brightness difference between the arc striking head and the arc striking tail is relatively large.

In this embodiment, specifically, the brightness of each end region is any one of the average value of the brightness of all pixels in the end region, the brightness of a pixel at an intermediate position in the end region, or the brightness of a pixel at an arbitrary position in the end region. Those skilled in the art may flexibly select how to determine the brightness of the two end regions.

For each end region, the average value of brightness of all pixels in the region may be calculated and determined as the brightness corresponding to the end region. The average value of brightness can more accurately and comprehensively reflect the brightness corresponding to the entire end region.

The formulas for calculating the average value of brightness of all pixels in the two end regions are as follows:

$${m}_{head} = \frac{1}{{I}_{head}} {\sum }_{{i}_{head} = 1}^{{I}_{head}} {m}_{{i}_{head}}$$

$${m}_{tail} = \frac{1}{{I}_{tail}} {\sum }_{{i}_{tail} = 1}^{{I}_{tail}} {m}_{{i}_{tail}}$$

m_{head} denotes the average value of brightness of the end region box_{head} corresponding to the head end. mₜₐᵢₗ denotes the average value of brightness of the end region box tail corresponding to the tail end. I_{head} denotes the number of pixels in the end region box_{head} corresponding to the head end. Iₜₐᵢₗ denotes the number of pixels in the end region box tail corresponding to the tail end. i_{head} denotes a pixel index in the end region corresponding to the head end. iₜₐᵢₗ denotes a pixel index in the end region corresponding to the tail end. Mᵢ_{_{head}} denotes the brightness of i_{head}. denotes the brightness of iₜₐᵢₗ.

In the arc striking phenomenon, the brightness from the arc striking head to the arc striking tail usually decreases gradually. Therefore, when it is judged whether the arc striking phenomenon occurs, it also needs to detect whether the brightness from one end to the other end is monotonically increasing or monotonically decreasing. If the brightness from one end to the other end is monotonically increasing or monotonically decreasing, it indicates that the elongated highlight region meets the condition that the brightness from the arc striking head to the arc striking tail decreases gradually. If the brightness from one end of the elongated highlight region to the other end of the elongated highlight region decreases gradually, it indicates that the starting end is the arc striking head while the other end is the arc striking tail. If the brightness from one end of the elongated highlight region to the other end of the elongated highlight region increases gradually, it indicates that the starting end is the arc striking tail while the other end is the arc striking head.

In this embodiment, specifically, judging whether the brightness from one end to the other end of the elongated highlight region is monotonically increasing or monotonically decreasing includes the following.

A brightness section line from one end of the elongated highlight region to the other end of the elongated highlight region is constructed. Pixels uniformly along the brightness section line are sampled, and if the brightness of all the sampled pixels is monotonically increasing or monotonically decreasing, the brightness from one end to the other end of the elongated highlight region is monotonically increasing or monotonically decreasing.

Here, the brightness section line is any one of a straight line, a polyline, or a curve.

In one or more embodiments, a method for judging that the brightness from one end of the elongated highlight region to the other end of the elongated highlight region is monotonically increasing or monotonically decreasing is as follows.

The average value of the brightness of all pixels in each sub-region is taken as the brightness of each sub-region, which is presented in the following formula:

$${a}_{mn} = \frac{1}{{J}_{n}} {\sum }_{{j}_{n} = 1}^{{J}_{n}} {L}_{{j}_{n}}$$

aₘₙ denotes the average value of the brightness of all pixels in an n-th sub-region. n=1, 2, . . . , N. Jₙ denotes the number of pixels in the n-th sub-region. jₙ denotes a pixel index in the n-th sub-region. Lⱼ_{ₙ} denotes the brightness of jₙ.

The brightness of adjacent sub-regions is compared sequentially according to the extension direction from one end to the other end.

If the brightness of the latter sub-region is always greater than the brightness of the previous sub-region, it is determined that the brightness from one end of the elongated highlight region to the other end of the elongated highlight region is monotonically increasing. If the brightness of the latter sub-region is always smaller than the brightness of the previous sub-region, it is determined that the brightness from one end of the elongated highlight region to the other end of the elongated highlight region is monotonically decreasing.

To more accurately detect whether the brightness of the elongated highlight region is monotonically decreasing or monotonically increasing, the number of divided sub-regions may be selected as integers such as 4, 5, 6, 7, 8, 9, and 10. However, the number for division should not be excessively great to prevent an increase in computational complexity and improve computational efficiency and the efficiency of abnormality identification.

In some embodiments, a method for judging that the brightness from one end of the elongated highlight region to the other end of the elongated highlight region is monotonically increasing or monotonically decreasing is as follows.

The average value of the brightness of all pixels in each sub-region is taken as the brightness of each sub-region.

A brightness difference between the brightness of the latter sub-region and the brightness of the previous sub-region is determined according to the extension direction from one end to the other end to obtain (N−1) brightness differences.

For example, the elongated highlight region is divided into four sub-regions. That is, N=4. One brightness difference is between the second sub-region and the first sub-region. One brightness difference is between the third sub-region and the second sub-region. One brightness difference is between the fourth sub-region and the third sub-region. Accordingly, a total of three brightness differences are obtained.

In this embodiment, the brightness difference between the brightness of the latter sub-region and the brightness of the previous sub-region is obtained by subtracting the brightness of the previous sub-region from the brightness of the latter sub-region.

The number of brightness differences greater than 0 and the number of brightness differences less than 0 among the (N−1) brightness differences are counted, which is presented in the following formulas:

$${r}_{1} = {\sum }_{n - 1 = 1}^{N} {x}_{n - 1} , {x}_{n - 1} = \{ \begin{matrix}1 , & {b}_{mn} - {b}_{mn - 1} > 0 \\ 0 , & {b}_{mn} - {b}_{mn - 1} \leq 0\end{matrix}$$

$${r}_{2} = {\sum }_{n - 1 = 1}^{N} {x}_{n - 1} , {x}_{n - 1} = \{ \begin{matrix}1 , & {b}_{mn} - {b}_{mn - 1} < 0 \\ 0 , & {b}_{mn} - {b}_{mn - 1} \geq 0\end{matrix}$$

r₁ denotes the number of brightness differences greater than 0 among the (N−1) brightness differences. r₂ denotes the number of brightness differences less than 0 among the (N−1) brightness differences. n denotes a sub-pixel index. N denotes the number of the sub-regions. bₘₙ denotes the brightness of an n-th sub-region. bₘₙ₋₁ denotes the brightness of an (n−1)-th sub-region.

If the number of brightness differences greater than 0 among the (N−1) brightness differences or the number of brightness differences less than 0 among the (N−1) brightness differences is greater than a preset brightness increase count judgment threshold, it is determined that the brightness from one end to the other end of the elongated highlight region is monotonically increasing or monotonically decreasing.

For example, the elongated highlight region is divided into four sub-regions. Brightness values corresponding to the first sub-region to the fourth sub-region are 15, 12, 20, and 25, respectively. Three brightness differences are −3, 8, and 5, respectively. The number of brightness differences greater than 0 among the three brightness differences is 2, and the number of brightness differences less than 0 among the three brightness differences is 1. When the set brightness increase count judgment threshold is 1.8, the number of brightness differences greater than 0 among the three brightness differences is greater than 1.8. In this case, it is determined that the brightness from one end of the elongated highlight region to the other end of the elongated highlight region is monotonically increasing or monotonically decreasing.

In a practical application, the brightness of an arc striking image captured via the cabinet interior image may be uneven. The brightness of the arc striking bright light gradually increases or decreases as a whole during the arc striking phenomenon, but local brightness flickering may occur. For example, arc striking shows a trend of decreasing brightness as a whole. However, the brightness of the latter region is greater than the brightness of the previous region at some two adjacent ends due to the instability of the arc striking phenomenon, not satisfying the decreasing trend. In this case, the entire trend may be judged as a whole. In this embodiment, if any one of the number of brightness differences greater than 0 among the (N−1) brightness differences or the number of brightness differences less than 0 among the (N−1) brightness differences is greater than the brightness increase count judgment threshold, it indicates that the proportion of the number that satisfies decreasing or increasing is large, thus satisfying increasing or decreasing in the entire trend. Such an arrangement can well avoid the missed judgment of arc striking and improve the accuracy of detecting the arc striking phenomenon.

In this embodiment, if only one elongated highlight region exists in the cabinet interior image, the end regions corresponding to the two ends of the elongated highlight region are constructed.

The elongated highlight region is divided into a plurality of sub-regions. It is judged whether the number of elongated highlight targets contained in each sub-region is 1. If the number of elongated highlight targets contained in each sub-region is 1, it is judged whether the brightness difference between the two end regions is greater than the preset brightness difference threshold. If the brightness difference between the two end regions is greater than the preset brightness difference threshold, it is judged whether the brightness change from one end to the other end is monotonically increasing or monotonically decreasing. If the brightness change from one end to the other end is monotonically increasing or monotonically decreasing, it is determined that the arc striking phenomenon occurs in the power distribution cabinet.

Many factors that cause the highlight in the image may exist in the power distribution cabinet. For example, the lighting of a normal indicator and the reflection of the surface of the device may form a highlight region, which does not belong to an arc striking phenomenon. It can be accurately determined that the arc striking phenomenon exactly occurs in the power distribution cabinet only when the highlight in the image is completely caused by the arc striking phenomenon and when no highlight image caused by other reasons exists. Therefore, the premise that only one highlight is contained in the cabinet interior image can effectively avoid the misjudgment of the arc striking phenomenon caused by the interference of other irrelevant highlight images.

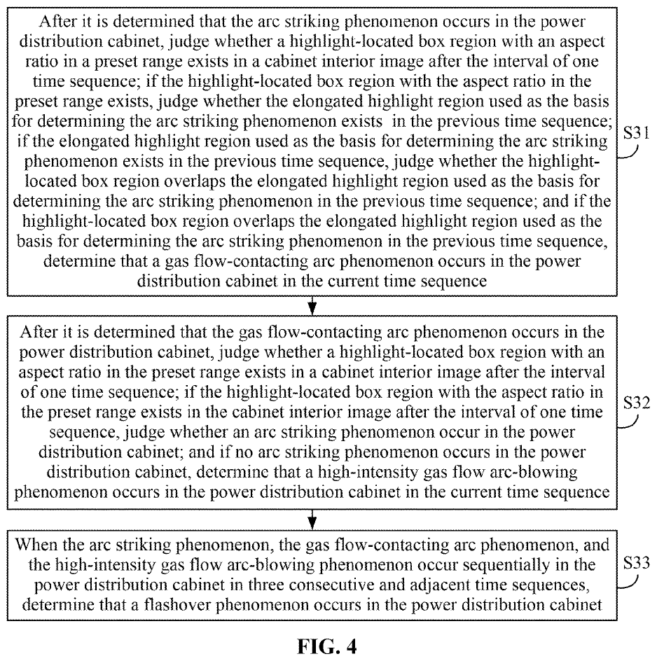

As shown in FIG. 4, FIG. 4 is a flowchart illustrating the identification of a flashover phenomenon.

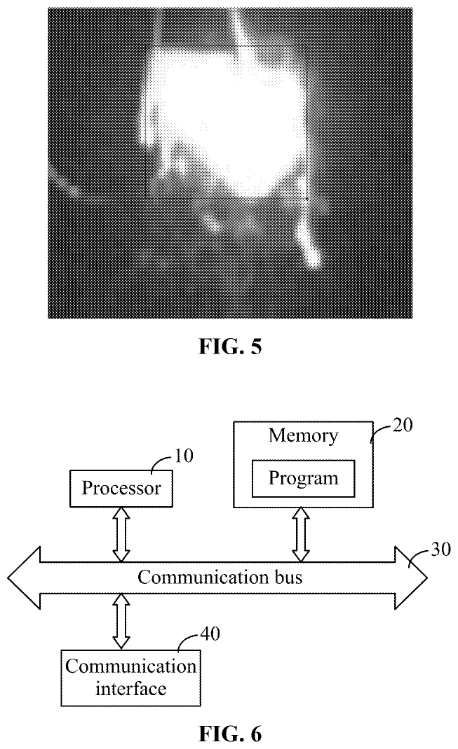

As shown in FIG. 5, FIG. 5 illustrates a diagram of the identified highlight-located box region in the case where the cabinet interior image includes the arc striking phenomenon.

In this embodiment, specifically, in step S31, after it is determined that the arc striking phenomenon occurs in the power distribution cabinet, it is judged whether a highlight-located box region with an aspect ratio in the range of 0.7 to 1.3 exists in a cabinet interior image after the interval of one time sequence and whether the elongated highlight region used as the basis for determining the arc striking phenomenon exists in the previous time sequence; if the highlight-located box region with the aspect ratio in the range of 0.7 to 1.3 exists in the cabinet interior image after the interval of one time sequence and the elongated highlight region used as the basis for determining the arc striking phenomenon exists in the previous time sequence, it is judged whether the highlight-located box region overlaps the elongated highlight region used as the basis for determining the arc striking phenomenon in the previous time sequence; and if the highlight-located box region overlaps the elongated highlight region used as the basis for determining the arc striking phenomenon in the previous time sequence, it is determined that a gas flow-contacting arc phenomenon occurs in the power distribution cabinet in the current time sequence.

When the gas flow comes into contact with the burning arc, the gas flow may cause disturbance to the arc and change the gas flow field and energy distribution around the arc. On the cabinet interior image, this disturbance is represented as a new highlight region, and the aspect ratio of the box region where the highlight region is located is in the range of 0.7 to 1.3, overlapping the original arc elongated highlight region. This is because the gas flow brings a new energy source or changes the material distribution in the original arc region so that the highlight feature also appears in this new region and interacts with the original arc region. Therefore, when such an image feature appears, it may be determined that the gas flow-contacting arc phenomenon occurs in the power distribution cabinet.

In step S32, after it is determined that the gas flow-contacting arc phenomenon occurs in the power distribution cabinet, it is judged whether a highlight-located box region with an aspect ratio in a preset range exists in a cabinet interior image after the interval of one time sequence and whether no arc striking phenomenon occurs in the power distribution cabinet; and if the highlight-located box region with the aspect ratio in the preset range exists in the cabinet interior image after the interval of one time sequence and no arc striking phenomenon occurs in the power distribution cabinet, it is determined that a high-intensity gas flow arc-blowing phenomenon occurs in the power distribution cabinet in the current time sequence.

When the gas flow strongly blows the arc, the strong gas flow may blow away the arc, causing the arc to be extinguished. In this case, no new arc striking phenomenon occurs in the distribution cabinet. However, the energy of the gas flow still exists and may form a highlight region on the cabinet interior image. The aspect ratio of the box region where the highlight region is located is within the preset range. This is because the gas flow may carry materials heated by the arc or the gas flow interacts with other materials in the power distribution cabinet to generate a luminescence phenomenon. Therefore, in the case of no arc striking, the image feature of a highlighted region with a specific shape appears so that it can be determined that the high-intensity gas flow arc-blowing phenomenon occurs in the power distribution cabinet.

In step S33, when the arc striking phenomenon, the gas flow-contacting arc phenomenon, and the high-intensity gas flow arc-blowing phenomenon occur sequentially in the power distribution cabinet in three consecutive and adjacent time sequences, it is determined that a flashover phenomenon occurs in the power distribution cabinet.

Flashover is a phenomenon of gas discharge along an insulating surface, usually accompanied by a series of complex physical processes. Arc striking is the initial stage of flashover. Then the gas flow contacts the arc, changing the shape and energy distribution of the arc. Finally, the gas flow strongly blows the arc, causing the arc to be extinguished or the energy of the arc to be greatly weakened. Such a series of phenomena appear in sequence, reflecting the process of energy generation, transmission and dissipation in the flashover process. Therefore, when it is detected that these three phenomena occur sequentially, it can be determined that the flashover phenomenon occurs in the power distribution cabinet.

A pre-trained highlight region detection model is used to detect the highlight-located box region in the image. The preceding region with a large area is the maximum bounding ellipse of the elongated highlight region and close to a circle; that is, the absolute value of the length difference between the long axis and the short axis of maximum bounding ellipse of the elongated highlight region is less than a preset first length threshold, and a ratio of the area of the elongated highlight region to the area of the maximum bounding ellipse of the elongated highlight region is greater than 0.7. Alternatively, the region with a large area is the maximum bounding rectangle and close to a square; that is, the absolute value of the difference between the length and the width of maximum bounding rectangle of the elongated highlight region is less than a preset second length threshold, and a ratio of the area of the elongated highlight region to the area of the maximum bounding rectangle of the elongated highlight region is greater than 0.7.

Among the three consecutive and adjacent time sequences, the previous time sequence and the adjacent next time sequence are two timing sequences within a preset duration. That is, an interval between the two adjacent time sequences is within the preset duration. The preset duration may be any duration of 1 second to 5 seconds. Those skilled in the art may set the interval between the two adjacent time sequences according to the specific occurrence duration of the flashover. By judging whether the arc striking phenomenon, the gas flow-contacting arc phenomenon, and the high-intensity gas flow arc-blowing phenomenon occur in the power distribution cabinet in the three adjacent time sequences, it can be accurately judged whether the flashover occurs.

According to embodiment one, various types of abnormal situations can be detected according to different displays of highlight regions in the cabinet interior image so that prompt information can be sent to maintenance staff in time according to the situations.

This embodiment further includes that when it is detected that the arc striking phenomenon occurs in the power distribution cabinet, abnormality prompt information is sent to a user-end device. The abnormality prompt information is used to prompt an abnormal situation of arc striking occurring in the power distribution cabinet.

In a practical application, the fault warning of the power distribution cabinet is usually known by maintenance staff only after a user feeds back an electrical device failure or after a circuit component reports an error. In this case, the component has already failed, making maintenance complicated and the maintenance cost relatively high and having a relatively great effect on user electricity consumption.

The present application overcomes the defect that the discontinuous arc striking phenomenon is not easily detected in a conventional inspection manner and causes the device failure to be difficult to find and prevent in time. Through the visual identification of the arc striking phenomenon, the hidden danger of the power distribution cabinet can be found in time. Abnormality can be quickly detected before the device failure, thereby avoiding further device failure. Accordingly, maintenance can be performed as soon as possible to reduce the maintenance cost and reduce the effect on user electricity consumption.

Embodiment two of the present application provides a system for detecting an arc striking phenomenon in a power distribution cabinet. The system includes an image collection module, an end region construction module, and a judgment module.

The image collection module is configured to acquire a cabinet interior image of the power distribution cabinet.

The end region construction module is configured to, when an elongated highlight region exists in the cabinet interior image, construct end regions corresponding to two ends of the elongated highlight region.

The judgment module is configured to: divide the elongated highlight region into a plurality of sub-regions; judge whether the number of elongated highlight targets contained in each sub-region is 1; if the number of elongated highlight targets contained in each sub-region is 1, judge whether a brightness difference between the two end regions of the elongated highlight region is greater than a preset brightness difference threshold; if the brightness difference between the two end regions of the elongated highlight region is greater than the preset brightness difference threshold, judge whether a brightness change from one end to the other end is monotonically increasing or monotonically decreasing; and if the brightness change from one end to the other end is monotonically increasing or monotonically decreasing, determine that the arc striking phenomenon occurs in the power distribution cabinet.

In this embodiment, specifically, the image collection module may be a binocular camera, a monocular camera, or a camera of another type. A camera is mounted in the power distribution cabinet to capture the cabinet interior image. The camera may be mounted in the power distribution cabinet by magnetic attraction or may be connected in the power distribution cabinet through a bolt, in a snap connection, or in other connection manners. The number of cameras may be one or multiple. Cameras are mounted at multiple positions to capture the cabinet interior images of the power distribution cabinet from different angles, which is not specifically limited in the present application.

Referring to FIG. 6, embodiment three of the present application further provides a device for detecting an arc striking phenomenon in a power distribution cabinet. The device includes a processor 10, a memory 20, a communication bus 30, and a communication interface 40.

The memory 20 is configured to store a computer program. The processor 10 is configured to, when executing the computer program, perform steps in the preceding method for detecting the arc striking phenomenon in the power distribution cabinet.

Embodiment four of the present application further provides a computer-readable storage medium for storing a computer program. When the computer program is executed by a processor, steps in the preceding method for detecting the arc striking phenomenon in the power distribution cabinet are performed.

It is to be understood by those skilled in the art that the embodiments of the present application may be provided as methods, systems, or computer program products. Therefore, the present application may adopt complete hardware embodiments, complete software embodiments, or a combination of hardware and software embodiments. In addition, the present application may adopt the form of a computer program product implemented on one or more computer-usable storage media (including, but not limited to, a disk memory, a CD-ROM, and an optical memory) that include computer-usable program codes.

The present application is described with reference to flowcharts and/or block diagrams of methods, devices (systems), and computer program products according to the embodiments of the present application. It is to be understood that computer program instructions may implement each flow and/or block in the flowcharts and/or block diagrams and a combination of flows and/or blocks in the flowcharts and/or block diagrams. These computer program instructions may be provided to a processor of a general-purpose computer, a special-purpose computer, an embedded processor, or another programmable data processing device to produce a machine so that instructions executed by the processor of the computer or another programmable data processing device create an apparatus for implementing functions specified in one or more flows in the flowcharts and/or in one or more blocks in the block diagrams.

These computer program instructions may also be stored in a computer-readable memory which can direct a computer or another programmable data processing device to operate in a particular manner so that instructions stored in the computer-readable memory create an article of manufacture including an instructing apparatus for implementing functions specified in one or more flows in the flowcharts and/or in one or more blocks in the block diagrams.

These computer program instructions may also be loaded onto a computer or another programmable data processing device so that a series of operation steps are performed on the computer or another programmable device to produce processing implemented by the computer. Therefore, instructions executed on the computer or another programmable device provide steps for implementing functions specified in one or more flows in the flowcharts and/or in one or more blocks in the block diagrams.

What is claimed is:

1. A method for detecting an arc striking phenomenon in a power distribution cabinet, comprising the following steps:
acquiring a cabinet interior image of the power distribution cabinet; and in response to an elongated highlight region in the cabinet interior image, constructing end regions corresponding to two ends of the elongated highlight region;
dividing the elongated highlight region into a plurality of sub-regions; wherein in response to that an angle between a line connecting one end to the other end of the two ends of the elongated highlight region and a horizontal direction is less than 45°, the elongated highlight region is vertically divided into the plurality of sub-regions; in response to that the angle between the line connecting the one end to the other end of the two ends of the elongated highlight region and the horizontal direction is greater than 45°, the elongated highlight region is horizontally divided into the plurality of sub-regions; and in response to that the angle between the line connecting the one end to the other end of the two ends of the elongated highlight region and the horizontal direction is equal to 45°, the elongated highlight region is horizontally or vertically divided into the plurality of sub-regions; and
judging whether a number of elongated highlight targets contained in each sub-region among the plurality of sub-regions is 1; in response to the number of elongated highlight targets contained in each sub-region being 1, judging whether a brightness difference between the two end regions of the elongated highlight region is greater than a preset brightness difference threshold; in response to the brightness difference between the two end regions of the elongated highlight region being greater than the preset brightness difference threshold, judging whether a brightness change from the one end to the other end of the two ends of the elongated highlight region is monotonically increasing or monotonically decreasing; and in response to the brightness change being monotonically increasing or monotonically decreasing, determining that the arc striking phenomenon occurs in the power distribution cabinet.

2. The method for detecting the arc striking phenomenon in the power distribution cabinet according to claim 1, wherein the cabinet interior image is input into a pre-trained target detection model to identify a highlight-located box region in the cabinet interior image; and
it is judged whether an aspect ratio of the highlight-located box region in the cabinet interior image is greater than a preset ratio, in response to the aspect ratio of the highlight-located box region being greater than the preset ratio, it is determined that a highlight region in the highlight-located box region in the cabinet interior image is elongated, and the highlight region is extracted to obtain the elongated highlight region.

3. The method for detecting the arc striking phenomenon in the power distribution cabinet according to claim 2, wherein after it is determined that the arc striking phenomenon occurs in the power distribution cabinet, the method further comprises:
judging whether a highlight-located box region whose aspect ratio is in a preset range exists in a cabinet interior image after an interval of one time sequence; in response to the highlight-located box region with the aspect ratio in the preset range existing, judging whether the elongated highlight region used as a basis for determining the arc striking phenomenon exists in a previous time sequence; in response to the elongated highlight region used as the basis for determining the arc striking phenomenon existing in the previous time sequence, judging whether the highlight-located box region overlaps the elongated highlight region used as the basis for determining the arc striking phenomenon in the previous time sequence; and in response to the highlight-located box region overlapping the elongated highlight region used as the basis for determining the arc striking phenomenon in the previous time sequence, determining that a gas flow-contacting arc phenomenon occurs in the power distribution cabinet in a current time sequence; wherein an upper limit of the preset range is less than the preset ratio;
after it is determined that the gas flow-contacting arc phenomenon occurs in the power distribution cabinet, judging whether a highlight-located box region whose aspect ratio is in the preset range exists in a cabinet interior image after an interval of one time sequence; in response to the highlight-located box region with the aspect ratio in the preset range existing, judging whether an arc striking phenomenon occur in the power distribution cabinet; and in response to no arc striking phenomenon occurring in the power distribution cabinet, determining that a high-intensity gas flow arc-blowing phenomenon occurs in the power distribution cabinet in a current time sequence; and
in response to the arc striking phenomenon, the gas flow-contacting arc phenomenon, and the high-intensity gas flow arc-blowing phenomenon occurring in the power distribution cabinet sequentially in three consecutive and adjacent time sequences, determining that a flashover phenomenon occurs in the power distribution cabinet.

4. The method for detecting the arc striking phenomenon in the power distribution cabinet according to claim 1, wherein an end region corresponding to each of the two ends is constructed based on two end positions of the elongated highlight region and an average width of the elongated highlight region.

5. The method for detecting the arc striking phenomenon in the power distribution cabinet according to claim 4, wherein an acquisition process of the average width of the elongated highlight region comprises:
drawing, according to a direction perpendicular to a long side of a minimum bounding rectangle of the elongated highlight region, a plurality of line segments penetrating the elongated highlight region and spaced apart with a preset interval, calculating an average value of a distance between two points where each line segment among the plurality of line segments intersects a boundary of the elongated highlight region, and taking the average value as the average width of the elongated highlight region.

6. The method for detecting the arc striking phenomenon in the power distribution cabinet according to claim 5, wherein constructing the end region corresponding to each of the two ends based on the two end positions of the elongated highlight region and the average width of the elongated highlight region comprises:
taking each end position among the two end positions as a center and the average width of the elongated highlight region as a side length or a diameter to construct a square region or a circular region as the end region corresponding to each of the two ends.

7. The method for detecting the arc striking phenomenon in the power distribution cabinet according to claim 1, wherein in response to that a number of elongated highlight targets contained in a sub-region among the plurality of sub-regions in the elongated highlight region is greater than 1, it is determined that the elongated highlight region does not meet a condition for the arc striking phenomenon, no subsequent judgment is performed, and a next elongated highlight region is processed.

8. The method for detecting the arc striking phenomenon in the power distribution cabinet according to claim 1, wherein a method for judging whether brightness from the one end to the other end of the elongated highlight region is monotonically increasing or monotonically decreasing comprises:
taking an average value of brightness of all pixels in each sub-region as brightness of each sub-region;
among the plurality of sub-regions, determining a brightness difference between brightness of a latter sub-region and brightness of a previous sub-region according to an extension direction from the one end to the other end of the elongated highlight region to obtain (N−1) brightness differences, wherein N denotes a number of the plurality of sub-regions; and
among the (N−1) brightness differences, counting a number of brightness differences greater than 0 and a number of brightness differences less than 0; in response to that the number of brightness differences greater than 0 is greater than a preset brightness difference count judgment threshold, determining that the brightness from the one end to the other end of the elongated highlight region is monotonically increasing; and in response to that the number of brightness differences less than 0 is greater than the preset brightness difference count judgment threshold, determining that the brightness from the one end to the other end of the elongated highlight region is monotonically decreasing.
